(19) United States
(12) Patent Application Publication
(10) Pub. No.: US 2026/0323874 A1
(43) Pub. Date: Oct. 15, 2026

(54) JUNCTION BOX AND TEST EQUIPMENT

(71) Applicant: Foxconn Internet Advanced Technology (Shaoxing) Co., Ltd, Shaoxing (CN)

(72) Inventors: MING-YUAN WU, Shaoxing (CN); CHUN-YU SHIH, New Taipei (TW); CHUN-YAN ZHANG, Shaoxing (CN)

(21) Appl. No.: 19/637,103

(22) Filed: Apr. 2, 2026

(30) Foreign Application Priority Data
Apr. 9, 2025 (CN) 202520663423.5

(51) Int. Cl. H05K 7/20; G01M 13/00

(52) U.S. Cl. CPC H05K 7/20272; G01M 13/00; H05K 7/20281

(57) ABSTRACT

This application relates to the field of multifunctional testing technology, and discloses a junction box and a test equipment. The junction box includes a pipeline system and a control system. The pipeline system includes an inlet pipeline, an outlet pipeline, a plurality of inlet branch pipes, and a plurality of outlet branch pipes. One end of each inlet branch pipe is connected to the inlet pipeline, and the other end of each inlet branch pipe is connected to a functional equipment. One end of each outlet branch pipe is connected to the outlet pipeline, and the other end of each outlet branch pipe is connected to the functional equipment. The inlet pipeline communicates with an inlet branch pipe. The outlet pipeline communicates with an outlet branch pipe. The control system selectively controls one inlet branch pipe, one outlet branch pipe, and the corresponding functional equipment to be connected.

The subject matter relates to multifunctional testing technology, and more particularly, to a junction box and a test equipment.

### BACKGROUND

With the rapid development of computer technology, the heat generation of servers has increased dramatically, and traditional air cooling systems can no longer meet the demand. Liquid cooling systems, by directly introducing coolant into the server, can significantly improve the efficiency of heat absorption and dissipation, ensuring stable operation of the equipment. The market demand for the production capacity of liquid cooling systems is growing rapidly.

During the manufacturing process of liquid cooling systems, it is necessary to perform gas-liquid leak detection on the liquid cooling pipes of servers. After the gas-liquid leak detection is completed, multiple processes such as drainage, cleaning, and drying of the liquid cooling pipes are also required based on different customer needs. Each process corresponds to different functional equipment. The functional equipment is used to input fluid medium into the liquid cooling pipes. When performing different processes, the corresponding functional equipment needs to be connected to the test piece. The operational steps are complex, and testing efficiency is low.

Therefore, there is room for improvement in the art.

### BRIEF DESCRIPTION OF THE DRAWINGS

FIG. 1 is a schematic diagram view of the principle of a test equipment according to an embodiment of the present application.

FIG. 2 is a diagrammatic view of a junction box according to an embodiment of the present application.

FIG. 3 is a diagrammatic view of the principle of the junction box according to an embodiment of the present application.

FIG. 4 is a perspective diagrammatic view of a junction box according to an embodiment of the present application.

### DETAILED DESCRIPTION

Implementations of the present technology will now be described, by way of example only, with reference to the attached figures.

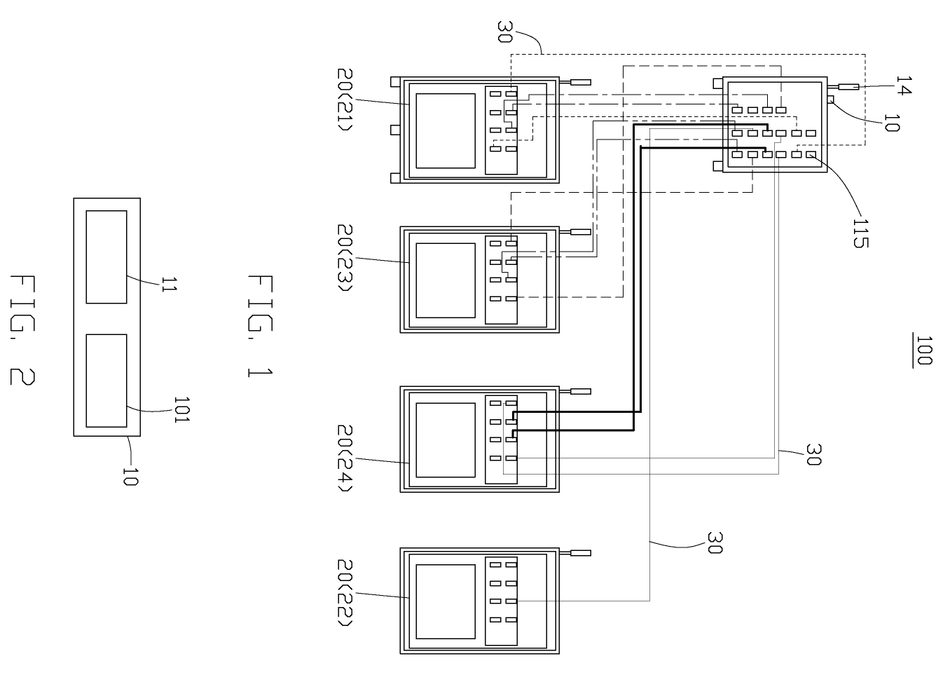

Referring to FIGS. 1, 2, and 3, an exemplary embodiment of the present application provides a test equipment 100. The test equipment 100 is configured to test a test piece 200. For example, the test piece 200 is a sensor box, a server, etc. The test piece 200 is provided with a liquid cooling pipe 201 used for filling coolant. The coolant could absorb the heat of the test piece 200.

The test equipment 100 includes a junction box 10 and a plurality of functional equipment 20. The plurality of functional equipment 20 are all communicated with the junction box 10. The junction box 10 is configured to connect to the test piece 200. The plurality of functional equipment 20 input fluid medium into the liquid cooling pipe 201 of the test piece 200 via the junction box 10 to test the test piece 200.

In an embodiment, the testing of the test piece 200 includes leak detection, liquid filling, drainage, cleaning, drying, etc. Correspondingly, the plurality of functional equipment 20 has functions such as leak detection, liquid filling, drainage, cleaning, and drying. The functional equipment 20 introduces different fluid media into the liquid cooling pipe 201 via the junction box 10, to perform tests such as leak detection, liquid filling, drainage, cleaning, and drying on the liquid cooling pipe 201. The fluid medium can be a gaseous medium such as compressed air, inert gas, or a liquid medium such as deionized water.

In an embodiment, referring to FIG. 1, in an embodiment, the test equipment 100 includes four functional equipment 20. The four functional equipment 20 are respectively a leak detection and drainage equipment 21, a liquid filling equipment 22, a cleaning equipment 23, and a drying equipment 24. The leak detection and drainage equipment 21, the liquid filling equipment 22, the cleaning equipment 23, and the drying equipment 24 respectively input the fluid medium within the functional equipment 20 into the liquid cooling pipe 201 via the junction box 10 to test the test piece 200.

Test equipment 100 centrally delivers fluid media for detection procedures such as leak detection, liquid injection, liquid drainage, cleaning and drying via the junction box 10, and connect to the test piece 200 via the junction box 10. Technicians do not need to switch the connections between the test piece 200 and the different functional equipment 20 back and forth, thereby improving test efficiency and simplifying the operation process.

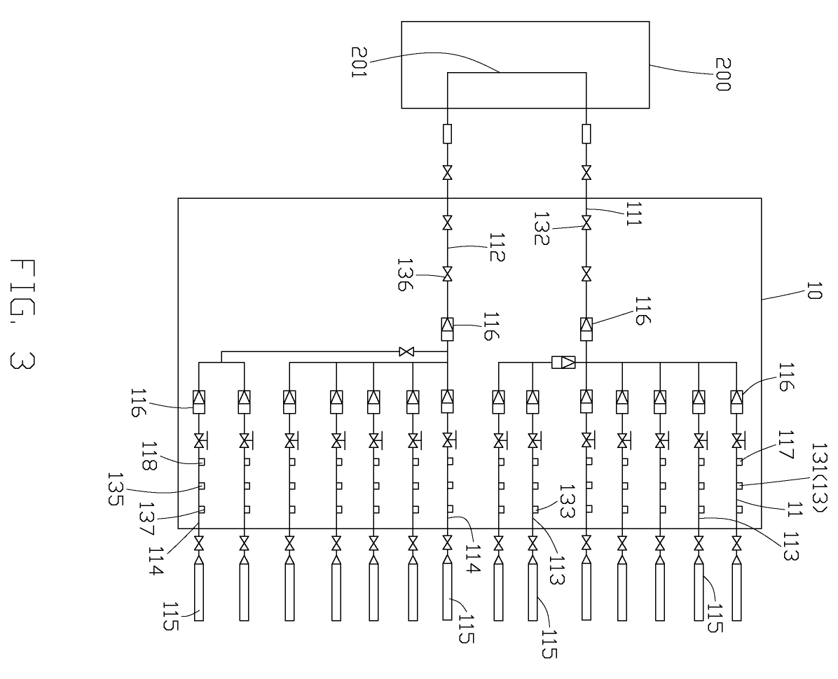

Referring to FIG. 2, in an embodiment, the junction box 10 includes a pipeline system 11 and a control system 101. The pipeline system 11 includes an inlet pipeline 111, an outlet pipeline 112, a plurality of inlet branch pipes 113 and a plurality of outlet branch pipes 114.

The plurality of inlet branch pipes 113 are arranged in parallel, with one end on the same side of each the inlet branch pipe 113 connected to the inlet pipeline 111, and the other end of each the inlet branch pipe 113 connected to a corresponding functional equipment 20. The inlet pipeline 111 is configured to communicate with the inlet branch pipe 113 to input fluid medium from the corresponding functional equipment 20 into the liquid cooling pipe 201.

The plurality of outlet branch pipes 114 are arranged in parallel, with one end on the same side of each the outlet branch pipe 114 connected to the outlet pipeline 112, and the other end of each the outlet branch pipe 114 connected to a corresponding functional equipment 20. The liquid cooling pipe 201 is connected between the inlet pipeline 111 and the outlet pipeline 112. The outlet pipeline 112 is configured to communicate with the outlet branch pipe 114 to allow the fluid medium in the liquid cooling pipe 201 to reflow to the corresponding functional equipment 20.

The control system 101 is connected to each the inlet branch pipe 113 and each the outlet branch pipe 114. The control system 101 is configured to selectively control one of the plurality of inlet branch pipes 113, one of the plurality of outlet branch pipes 114, and the corresponding functional equipment 20 to be connected.

The junction box 10 connects to the plurality of functional equipment 20, and controls the communication of different inlet branch pipes 113 and outlet branch pipes 114 through the control system 101, thereby connecting different functional equipment 20 to the test piece 200, allowing the fluid medium from different functional equipment 20 to enter the test piece 200 for testing.

The junction box 10 enables the connection of the test piece 200 to different functional equipment 20 at the same location for different functional tests, eliminating the need to switch back and forth between multiple functional equipment 20, which is beneficial for reducing manual intervention and lowering maintenance costs. The junction box 10 integrates the functions of multiple functional equipment 20 through the pipeline system 11, the junction box 10 can quickly respond to testing demands, reduce waiting time, and improve overall work efficiency.

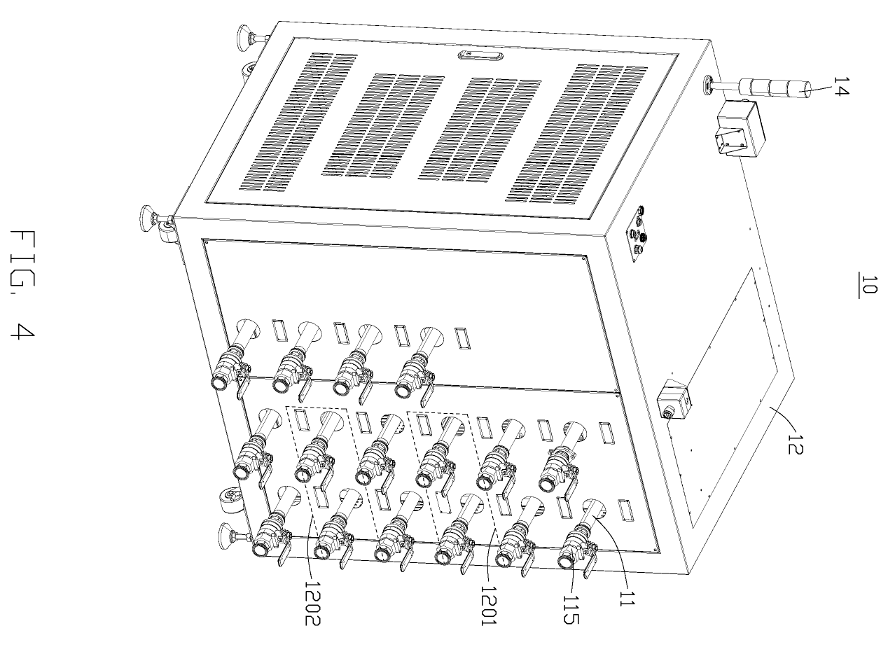

Referring to FIGS. 3 and 4, in an embodiment, the junction box 10 further includes a cabinet 12. An interior of the cabinet 12 defines a plurality of areas. One inlet branch pipe 113 and one outlet branch pipe 114 are arranged in each area, such as the area 1201 and the area 1202. The inlet branch pipe 113 and the outlet branch pipe 114 in each area are connected to a same functional equipment 20 of the plurality of areas.

The junction box 10 integrates the pipeline system 11 connected to different functional equipment 20 into the cabinet 12, consolidating the functions of originally scattered multiple functional equipment 20 onto a unified platform, reducing equipment footprint and improving space utilization.

In addition, arranging the inlet branch pipes 113 and outlet branch pipes 114 corresponding to different functional equipment 20 in different areas minimizes interference between the pipelines corresponding to different functional equipment 20. When a functional equipment 20 fails, the pipelines in the area corresponding to that functional equipment 20 can be quickly repaired, with less likelihood of affecting the normal operation of pipelines in other areas.

Referring to FIGS. 3 and 4, in an embodiment, the pipeline system 11 includes a plurality of connectors 115. The plurality of connectors 115 are used to adapt to different functional equipment 20. Each outlet branch pipe 114 is configured to be detachably connected to a connector 115. Each inlet branch pipe 113 is configured to be detachably connected to a connector 115. The outlet branch pipe 114 is communicated with the functional equipment 20 via the connector 115, and the inlet branch pipe 113 is communicated with the functional equipment 20 via the connector 115.

The structures of the plurality of connectors 115 could be different, thereby enabling different functional equipment 20 to connect to corresponding outlet branch pipes 114 or inlet branch pipes 113. The junction box 10 adopts detachable connectors 115. The connectors 115 could be selected according to the connection requirements of the functional equipment 20, taking into account the interface and protocol standards of various functional equipment 20. The junction box 10 is compatible with functional equipment 20 of different brands and models, giving a wider range of applications and a longer service life.

In an embodiment, the connector 115 is a sanitary clamp. The sanitary clamp is a standard fitting for connecting pipelines, with good sealing, enabling quick and convenient connection to the functional equipment 20.

In an embodiment, the connectors 115 are arranged outside the cabinet 12 to facilitate the connection to the functional equipment 20.

In addition, one of the plurality of connectors 115 is connected to the inlet pipeline 111, and one of the plurality of connectors 115 is connected to the outlet pipeline 112. The connector 115 can be selected to adapt to the structure of the test piece 200, enabling the connector 115 to connect to the test piece 200, thereby achieving the connection of the inlet pipeline 111 and the outlet pipeline 112 to the test piece 200.

In an embodiment, each inlet branch pipe 113 is detachably connected to the inlet pipeline 111, and each outlet branch pipe 114 is detachably connected to the outlet pipeline 112. When a pipeline fails, it is easy to completely disassemble and replace the faulty pipeline, thereby improving maintenance efficiency.

Referring to FIG. 3, in an embodiment, the pipeline system 11 further includes control valves 116. Each inlet branch pipe 113 and each outlet branch pipe 114 are respectively provided with a control valve 116. The control valve 116 is configured to be in communication connection with the control system 101. The control system 101 is configured to control the opening and closing of the control valve 116, thereby controlling the on or off state of the inlet branch pipes 113 and the outlet branch pipes 114.

For example, when a cleaning step needs to be performed, the control system 101 controls the control valve 116 on the inlet branch pipe 113 connected to the cleaning equipment 23 and the control valve 116 on the outlet branch pipe 114 to open, while the control valves 116 on other inlet branch pipes 113 and outlet branch pipes 114 connected to the cleaning equipment 23 are closed, causing the cleaning equipment 23 to perform a cleaning operation.

The control system 101, based on the test step to be performed, controls the opening of the control valve 116 on the pipeline connected to the corresponding functional equipment 20 for that test function, so that the functional equipment corresponding to the test function 20, the inlet branch pipe 113 is connected to the inlet pipeline 111, and the outlet branch pipe 114 connected to the required functional equipment 20 is connected to the outlet pipeline 112.

The control system 101 further controls the closing of the control valves 116 on the inlet branch pipes 113 and the inlet pipeline 111 connected to other functional equipment 20, thereby achieving connection of the test piece 200 to only one functional equipment 20 during testing.

The control system 101 is further configured to control and adjust the opening degree of the control valve 116 to change the cross-sectional area of the fluid medium passing through the valve of the control valve 116, thereby precisely controlling the flow rate of the medium in the pipeline.

Referring to FIG. 3, in an embodiment, the outlet pipeline 112 and the inlet pipeline 111 are provided with the control valve 116. The control valve 116 on the inlet pipeline 111 cooperates with the control valve 116 on the inlet branch pipe 113, and the control valve 116 on the outlet pipeline 112 cooperates with the control valve 116 on the outlet branch pipe 114 to control the on or off state of a certain node in the pipeline system 11.

In an embodiment, the control valve 116 is a check valve to reduce the backflow of fluid medium in the pipeline system 11.

Referring to FIG. 3, in an embodiment, the junction box 10 further includes a detection assembly 13. The detection assembly 13 is arranged on the pipeline system 11 and is connected to the control system 101. The control system 101 is configured to control the detection assembly 13 to detect the working state of the pipeline system 11, for example, to detect the state of the fluid medium inside the pipeline system 11. The control system 101 controls the operation of the pipeline system 11 based on feedback information from the detection assembly 13, for example, controlling the connection and disconnection of the pipeline system 11.

The arrangement of the detection assembly 13 enables timely feedback to the control system 101 when problems occur in the pipeline system 11, which is beneficial for protecting the pipelines.

Referring to FIG. 3, in an embodiment, the detection assembly 13 includes a plurality of first temperature sensors 131. Each inlet branch pipe 113 is installed with at least one first temperature sensor 131. The first temperature sensor 131 is configured to detect a temperature of the fluid medium inside the inlet branch pipe 113.

The detection assembly 13 includes a plurality of second temperature sensors 135. Each outlet branch pipe 114 is installed with at least one second temperature sensor 135. The second temperature sensor 135 is configured to detect a temperature of the fluid medium inside the outlet branch pipe 114.

The first temperature sensor 131 detects the temperature of the fluid medium in the inlet branch pipe 113, and the second temperature sensor 135 detects the temperature of the fluid medium in the outlet branch pipe 114, which is beneficial for the control system 101 to control the operation of the pipeline system 11 based on the temperature of the fluid medium, making the pipeline system 11 less prone to damage due to excessively high or low temperatures.

By independently installing at least one first temperature sensor 131 on each inlet branch pipe 113 and at least one second temperature sensor 135 on outlet branch pipe 114, the temperature at each node in the pipeline is individually collected, facilitating the timely detection of local abnormal temperature rises or fluctuations in the pipeline. Moreover, the binding relationship between the first temperature sensor 131 and the corresponding branch pipe, and between the second temperature sensor 135 and the corresponding branch pipe simplifies the fault location and replacement process. A failed first temperature sensor 131 or the second temperature sensor 135 can be quickly replaced without stopping the system, shortening maintenance cycles and reducing operation and maintenance costs.

Referring to FIG. 3, in an embodiment, the detection assembly 13 further includes first flow meters 132 and second flow meters 136. The inlet pipeline 111 isprovided with the first flow meter 132, and the outlet pipeline 112 is provided with the second flow meter 136. The first flow meter 132 detects the flow velocity of the fluid medium in the inlet pipeline 111, and the second flow meter 136 detects the flow velocity of the fluid medium in the outlet pipeline 112.

The first flow meter 132 could monitor the flow velocity of the fluid medium in the corresponding inlet pipeline 111, and the second flow meter 136 could monitor the flow velocity of the fluid medium in the corresponding outlet pipeline 112 in real time. Through accurate flow data, it monitors the input amount of fluid medium introduced by the functional equipment 20 into the test piece 200, improving the testing quality of the test piece 200. Moreover, by monitoring abnormal flow fluctuations in the pipeline, it can indicate faults such as pipeline damage, providing early warning of pipeline leaks and preventing accidents.

Referring to FIG. 3, in an embodiment, the detection assembly 13 further includes pressure sensors. The pipeline system 11 further includes pressure relief valves. Each inlet branch pipe 113 is provided with a first pressure sensor 133 of plurality of pressure sensors and a first pressure relief valve 117 of plurality of pressure relief valves. Each outlet branch pipe 114 is provided with a second pressure sensor 137 of plurality of pressure sensors and a second pressure relief valve 118 of plurality of pressure relief valves. The first pressure sensor 133 is configured to detect a pressure in each inlet branch pipe 113, and the second pressure sensor 137 is configured to detect a pressure in each outlet branch pipe 114.

Installing the first pressure sensor 133 on each inlet branch pipe 113 and the second pressure sensor 133 on each outlet branch pipe 114 independently allows precise capture of pressure fluctuations at different locations in the pipeline system 11, such as instantaneous peaks, abnormal low or high pressure, providing the control system 101 with high-frequency, multi-node pressure distribution data, avoiding overall system failures caused by local blockages, leaks, or flow imbalances.

By monitoring the pipeline pressure in real time, when the pressure exceeds the safety threshold, the control system 101 controls the pressure relief valve to activate, automatically regulating the pressure within the pipeline system 11 to prevent safety incidents such as pipeline rupture or explosion. A sudden pressure drop or abnormal fluctuation allows for rapid location of the leak point, shortening troubleshooting duration and reducing fluid medium loss.

In an embodiment, the control system 101 performs switch control, parameter adjustment, and protection monitoring on components such as the detection assembly 13, control valves 116, and pressure relief valves of each pipeline in the pipeline system 11 according to preset programs and external instructions.

By monitoring the operating status and parameter changes of the pipeline system 11 in real time, the control system 101 timely adjusts parameters such as air pressure and hydraulic pressure within the pipeline system 11 to ensure stable operation of each pipeline.

Referring to FIG. 4, in an embodiment, the junction box 10 includes an alarm 14. The alarm 14 is connected to the control system 101. When the control system 101 receives abnormal information detected by the detection assembly 13, the control system 101 controls the alarm 14 to issue an alert.

Referring to FIG. 1, in an embodiment, the test equipment 100 further includes a plurality of connecting pipes 30. The connecting pipes 30 connect the connectors 115 of the pipeline system 11 to the functional equipment 20. For example, one end of the connecting pipes 30 is connected to the connector 115 of the inlet branch pipe 113, and the other end is connected to the output end of one of the functional equipment 20.

In addition, those of ordinary skill in the art should understand that the above embodiments are only used to illustrate the present application and are not intended to limit the present application. Within the essential spirit and scope of the present application, appropriate modifications and changes made to the above embodiments shall fall within the scope of disclosure of the present application.

The terms used in the present application, such as “first” and “second”, do not intended to indicate any order, quantity, or importance of related components, but are only used for differentiation between the related components.

As used in the present application, the term “a” or “one” do not intended to limit the quantity of the related object, but to indicate the existence of at least one related object.

In the present application, the terms indicating direction or position, such as “top”, “bottom”, “side”, “longitudinal”, “transverse”, “middle”, “center, “outer”, “inner”, “horizontal”, “vertical”, “left”, “right”, “upper”, and “lower”, refers to a relative position rather than an absolute position.

The terms used in the present application, such as “substantially”, “whole”, “approximate”, and “similar”, are intended to indicate that the object has related characteristics but allow for certain deviations. The deviation may depend on a specific background. For example, the dimension of deviation may depend on a specific background, comprising but not limited to national standards for dimensional tolerances.

What is claimed is:

1. A junction box configured for connecting a test piece and a liquid cooling pipe of a plurality of functional equipment, the junction box comprising:
a pipeline system, the pipeline system comprising
an inlet pipeline;
an outlet pipeline;
a plurality of inlet branch pipes arranged in parallel, one end of each the inlet branch pipe communicating with the inlet pipeline, and another end of each the inlet branch pipe configured for communicating with a corresponding one of the functional equipment; and
a plurality of outlet branch pipes arranged in parallel, one end of each the outlet branch pipe communicating with the outlet pipeline, and another end of each he outlet branch pipe configured for communicating with a corresponding functional equipment of the functional equipment; the inlet pipeline configured for connecting between each of the plurality of inlet branch pipes and the liquid cooling pipe, and the outlet pipeline configured for connecting between each of the plurality of outlet branch pipes and the liquid cooling pipe; and
a control system, connected to the plurality of inlet branch pipes and the plurality of outlet branch pipes, the control system controlling each of the plurality of inlet branch pipes to communicate with the inlet pipeline, thereby inputting fluid medium from the corresponding functional equipment into the liquid cooling pipe; the control system further controlling each of the plurality of outlet branch pipes to communicate with the outlet pipeline, thereby reflowing the fluid medium in the liquid cooling pipe to the corresponding functional equipment.

2. The junction box to claim 1, wherein the pipeline system further comprises a plurality of connectors adapted to the plurality of functional equipment, each of the outlet branch pipes is detachably connected to a corresponding connector of the plurality of connectors, and each of the outlet branch pipe is connected to the corresponding functional equipment via the corresponding connector;
each of the inlet branch pipes is detachably connected to a corresponding connector of the plurality of connectors, and each of the inlet branch pipe is connected to the corresponding functional equipment via the corresponding connector.

3. The junction box to claim 2, wherein at least two of the plurality of connectors are adapted to different test pieces, the outlet pipeline is detachably connected to a connector of the at least two connectors, and the outlet pipeline is connected to the different test pieces via the connector of at least two connectors;
the inlet pipelines is detachably connected to another connector of the at least two connectors, and the inlet pipeline is connected to the different test pieces via the other connector of the at least two connectors.

4. The junction box to claim 1, wherein the junction box further comprises a detection assembly arranged on the pipeline system and connected to the control system, the control system further controls the detection assembly to detect a working state of the pipeline system, and control operations of the pipeline system based on feedback information from the detection assembly.

5. The junction box to claim 4, wherein the detection assembly comprises a plurality of first temperature sensors and a plurality of second temperature sensors, each of the plurality of inlet branch pipes is installed with the first temperature sensor, the first temperature sensor is electrically connected to the control system and configured to detect a temperature of the fluid medium in the inlet branch pipe;
each of the plurality of outlet branch pipes is installed with the second temperature sensor, and the second temperature sensor is configured to detect a temperature of the fluid medium in the outlet branch pipe.

6. The junction box to claim 4, wherein the detection assembly comprises a first flow meter and a second flow meters, the inlet pipeline is installed with the first flow meter, the outlet pipeline is installed with the second flow meter, the first flow meter and the second flow meter are electrically connected to the control system, the first flow meter is configured to detect a flow velocity of the fluid medium in the inlet pipeline, and the second flow meter is configured to detect a flow velocity of the fluid medium in the outlet pipeline.

7. The junction box to claim 4, wherein the detection assembly comprises a plurality of pressure sensors, the pipeline system further comprises a plurality of pressure relief valves, each of the plurality of pressure sensors and each of the plurality of pressure relief valves are electrically connected to the control system; each of the plurality of inlet branch pipes is installed with a first pressure sensor of the plurality of pressure sensors and a first pressure relief of the plurality of pressure relief valves, each of the plurality of outlet branch pipes is installed with a second pressure sensor of the plurality of pressure sensors and a second pressure relief valve of the plurality of pressure relief valves, wherein the first pressure sensor is configured to detect a pressure in the inlet branch pipe and the first pressure sensor transmits the pressure in the inlet branch pipe to the control system, or the second is configured to detect a pressure in the outlet branch pipe and the second pressure sensor transmits the pressure in the outlet branch pipe to the control system, and wherein the control system controls a corresponding pressure relief valve of the plurality of pressure relief valves to activate in response to any of the pressure detected by the first pressure sensor and the pressure detected by the second pressure sensor exceeding a safety threshold.

8. The junction box to claim 4, wherein the junction box further comprises an alarm, the alarm is connected to the control system, and the control system controls the alarm to issue an alert in response to the detection assembly detecting abnormal information.

9. The junction box to claim 1, wherein the pipeline system further comprises control valves, each of the plurality of inlet branch pipes is installed with a control valve of the control valves, each of the outlet branch pipes is installed with a control valve of the control valves, each of the control valves is electrically connected to the control system, and the control system is configured to control each of the control valves to open or to close, thereby controlling each of the plurality of inlet branch pipes and each of the plurality of outlet branch pipes to switch between an on state and an off state.

10. The junction box to claim 9, wherein each of the control valves is a check valve.

11. The junction box to claim 1, wherein the junction box further comprises a cabinet, an interior of the cabinet defines a plurality of areas, and the inlet branch pipe and the outlet branch pipe connected to a same functional equipment of the plurality of functional equipment are installed in a same area of the plurality of areas.

12. The junction box to claim 11, wherein each of the plurality of inlet branch pipes is detachably connected to the inlet pipeline, and each of the plurality of outlet branch pipes is detachably connected to the outlet pipeline.

13. A test equipment, comprising:
a plurality of functional equipment;
a junction box, each of the plurality of functional equipment is connected to a test piece via the junction box; the junction box comprising:
a pipeline system, the pipeline system comprising
an inlet pipeline;
an outlet pipeline;
a plurality of inlet branch pipes arranged in parallel, one end of each the inlet branch pipe communicating with the inlet pipeline, and another end of each the inlet branch pipe configured for communicating with a corresponding one of the functional equipment; and
a plurality of outlet branch pipes arranged in parallel, one end of each the outlet branch pipe communicating with the outlet pipeline, and another end of each he outlet branch pipe configured for communicating with a corresponding functional equipment of the functional equipment; the inlet pipeline configured for connecting between each of the plurality of inlet branch pipes and a liquid cooling pipe of the test piece, and the outlet pipeline configured for connecting between each of the plurality of outlet branch pipes and the liquid cooling pipe; and
a control system, connected to the plurality of inlet branch pipes and the plurality of outlet branch pipes, the control system controlling each of the plurality of inlet branch pipes to communicate with the inlet pipeline, thereby inputting fluid medium from the corresponding functional equipment into the liquid cooling pipe; the control system further controlling each of the plurality of outlet branch pipes to communicate with the outlet pipeline, thereby reflowing the fluid medium in the liquid cooling pipe to the corresponding functional equipment.

14. The test equipment to claim 13, wherein the pipeline system further comprises a plurality of connectors adapted to the plurality of functional equipment, each of the outlet branch pipes is detachably connected to a corresponding connector of the plurality of connectors, and each of the outlet branch pipe is connected to the corresponding functional equipment via the corresponding connector;
each of the inlet branch pipes is detachably connected to a corresponding connector of the plurality of connectors, and each of the inlet branch pipe is connected to the corresponding functional equipment via the corresponding connector.

15. The test equipment to claim 13, wherein the junction box further comprises a detection assembly arranged on the pipeline system and connected to the control system, the control system further controls the detection assembly to detect a working state of the pipeline system, and control operations of the pipeline system based on feedback information from the detection assembly.

16. The test equipment to claim 14, wherein the detection assembly comprises a plurality of first temperature sensors and a plurality of second temperature sensors, each of the plurality of inlet branch pipes is installed with the first temperature sensor, the first temperature sensor is electrically connected to the control system and configured to detect a temperature of the fluid medium in the inlet branch pipe;
each of the plurality of outlet branch pipes is installed with the second temperature sensor, and the second temperature sensor is configured to detect a temperature of the fluid medium in the outlet branch pipe.

17. The test equipment to claim 14, wherein the detection assembly comprises a first flow meter and a second flow meters, the inlet pipeline is installed with the first flow meter, the outlet pipeline is installed with the second flow meter, the first flow meter and the second flow meter are electrically connected to the control system, the first flow meter is configured to detect a flow velocity of the fluid medium in the inlet pipeline, and the second flow meter is configured to detect a flow velocity of the fluid medium in the outlet pipeline.

18. The test equipment to claim 14, wherein the detection assembly comprises a plurality of pressure sensors, the pipeline system further comprises a plurality of pressure relief valves, each of the plurality of pressure sensors and each of the plurality of pressure relief valves are electrically connected to the control system; each of the plurality of inlet branch pipes is installed with a first pressure sensor of the plurality of pressure sensors and a first pressure relief of the plurality of pressure relief valves, each of the plurality of outlet branch pipes is installed with a second pressure sensor of the plurality of pressure sensors and a second pressure relief valve of the plurality of pressure relief valves, wherein the first pressure sensor is configured to detect a pressure in the inlet branch pipe and the first pressure sensor transmits the pressure in the inlet branch pipe to the control system, or the second is configured to detect a pressure in the outlet branch pipe and the second pressure sensor transmits the pressure in the outlet branch pipe to the control system, and wherein the control system controls a corresponding pressure relief valve of the plurality of pressure relief valves to activate in response to any of the pressure detected by the first pressure sensor and the pressure detected by the second pressure sensor exceeding a safety threshold.

19. The test equipment to claim 13, wherein the junction box further comprises a cabinet, an interior of the cabinet defines a plurality of areas, and the inlet branch pipe and the outlet branch pipe connected to a same functional equipment of the plurality of functional equipment’s are installed in a same area of the plurality of areas.

20. The test equipment to claim 19, wherein each of the plurality of inlet branch pipes is detachably connected to the inlet pipeline, and each of the plurality of outlet branch pipes is detachably connected to the outlet pipeline.
